(19) United States
(12) Patent Application Publication
(10) Pub. No.: US 2026/0314377 A1
(43) Pub. Date: Oct. 8, 2026

(54) SEMICONDUCTOR DEVICE HAVING A LAYERED SOURCE PAD

(71) Applicant: Microchip Technology Incorporated, Chandler, AZ (US)

(72) Inventors: Shesh Mani Pandey, Gilbert, AZ (US); Sundar Babu Isukapati, Gilbert, AZ (US); Dennis Meyer, Chandler, AZ (US); Bruce Odekirk, Portland, OR (US)

(73) Assignee: Microchip Technology Incorporated, Chandler, AZ (US)

(21) Appl. No.: 19/300,881

(22) Filed: Aug. 15, 2025

Related U.S. Application Data
(60) Provisional application No. 63/784,662, filed on Apr. 7, 2025.

(51) Int. Cl. H10W 20/41; H10D 64/23; H10W 20/42; H10D 62/832; H10W 72/50; H10W 74/43

(52) U.S. Cl. CPC H10W 20/427; H10D 64/258; H10W 20/42; H10D 62/8325; H10W 72/541; H10W 74/43

(57) ABSTRACT

A semiconductor device includes a source electrode. The source electrode includes spaced apart first and second metal layers and a via extending between and electrically connecting the first metal layer and the second metal layer. The metal layer includes first and second source electrode contacts. The source second metal layer includes a monolithic source pad spaced apart from and electrically connected to the first and second source electrodes.

### CROSS-REFERENCE TO RELATED APPLICATIONS

The current patent application claims the benefit under 35 U.S.C. § 119(e) of the priority date of U.S. Provisional Application Ser. No. 63/784,662; titled “MOSFET HAVING LAYERED SOURCE PADS”; and filed Apr. 7, 2025. The Provisional Application is hereby incorporated by reference, in its entirety, into the current patent application.

### TECHNICAL FIELD

The present disclosure relates to transistors and, more particularly, to transistors having multiple source contacts.

### BACKGROUND

A transistor is an active, voltage-controlled semiconductor device, in which varying an electrical voltage between a gate and a body controls an electrical current flowing through a semiconductor channel between a drain and a source. Applications for transistors include amplifiers, switches, resistors, regulators, oscillators, and choppers. It is generally desirable to improve the performance and reduce the cost of transistors, but it can be difficult to do so.

This background discussion is intended to provide related information, and is not necessarily prior art.

### SUMMARY OF THE INVENTION

In various examples of the present disclosure, a semiconductor device includes a source electrode. The source electrode includes spaced apart first and second metal layers and a via extending between and electrically connecting the first metal layer and the second metal layer.

In various examples of the present disclosure, a semiconductor device includes first and second source electrode contacts and a monolithic source pad spaced apart from and electrically connected to the first and second source electrodes.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 is a perspective view of an example semiconductor device having a layered source pad;

FIG. 2 is partial cross-sectional front elevation view of the example semiconductor device of FIG. 1; and

FIG. 3 is a partial cross-sectional rear elevation view of the example semiconductor device of FIG. 1.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Generally, the use of a plurality of bond wires may introduce unwanted parasitic inductance and capacitances (e.g., parasitics) between components of a typical transistor. These parasitics may impact performance of the typical transistor due to volage overshoots, ringing oscillations, increased switching losses, and reduced switching speeds. Moreover, the plurality of bond wires may cause heating of the typical transistor due to a lack of heat dissipation relative to the bond wires.

Examples provide a semiconductor device having a layered source pad. The example transistor may be suitable for high-voltage applications, and may operate at a voltage greater than one thousand (1,000) Volts (V). It would be appreciated by one of ordinary skill in the art that the example transistor may be suitable for lower voltage applications (e.g., less than one thousand (1,000) V) without departing from the scope of the present disclosure. In various examples, the example semiconductor device may be a transistor, such as a metal-oxide semiconductor field-effect transistor (MOSFET), a junction field-effect transistor (JFET), and the like.

The layered source pad of the example semiconductor device may enable a reduced number of bond wires to be used in comparison to alternative transistors. The reduced number of bond wires may reduce unwanted parasitics, thereby improving the overall performance of the example semiconductor device. Additionally, the layered source pad may improve heat dissipation by spreading heat evenly across the layered source pad and ensure that electrical current is conveyed uniformly through the semiconductor device, thereby further improving performance of the semiconductor device by improving switching speeds, reducing switching loss, reducing ringing oscillations, and reducing voltage overshoots.

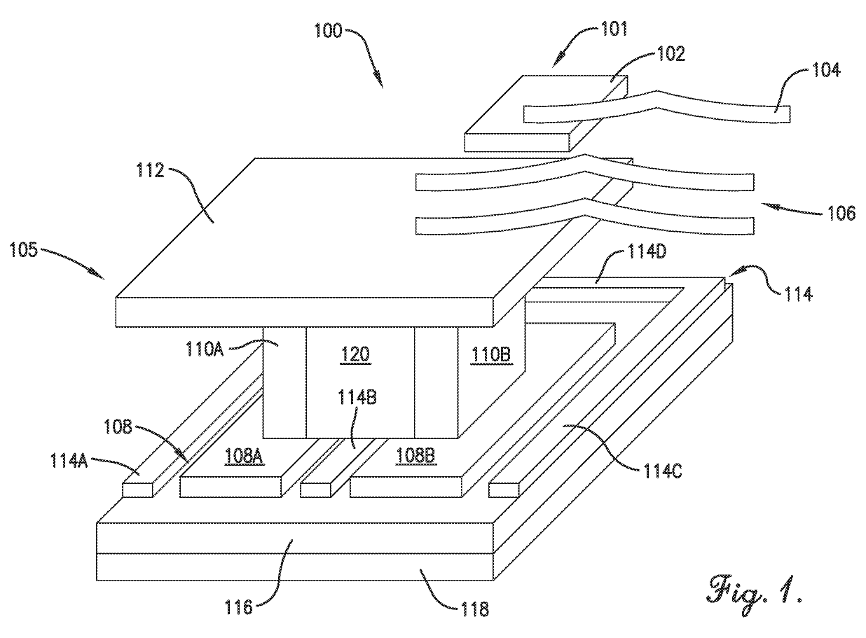

Referring to FIG. 1, an example of a semiconductor device 100 is shown. In various examples, the semiconductor device 100 may be a transistor. The semiconductor device 100 includes a gate electrode 101, a source electrode 105, a passivation layer 116, and a substrate 118. The semiconductor device 100 may be a standalone device or may be integrated with other semiconductor devices and/or integrated into a larger device, such as a power module, integrated circuit (IC), and the like.

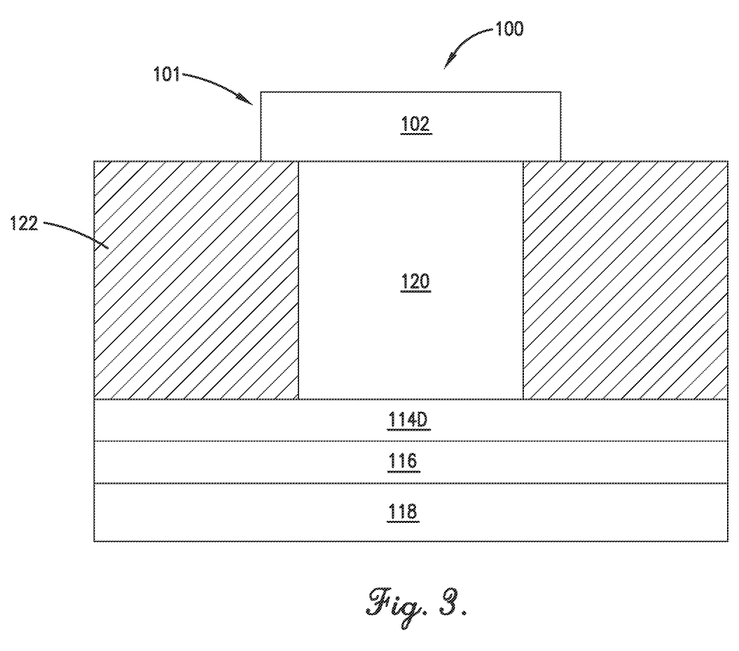

The gate electrode 101 includes a gate pad 102, a bond wire 104, and a gate electrode contact 114 spaced apart from the gate pad 102 along a vertical axis (e.g., a z-axis, as shown in FIG. 1). As shown in FIG. 3, the gate electrode 101 additionally includes a gate via 120 extending along the vertical axis between the gate pad 102 and the gate electrode contact 114. The bond wire 104 is electrically connected to the gate pad 102 such that an external voltage supplied to the gate pad 102 through the bond wire 104 enables electrical energy to flow from the gate pad 102, through the gate via 120, and to the gate electrode contact 114, thereby energizing the gate electrode contact 114. When the gate electrode contact 114 is energized by an appropriate voltage, the semiconductor device 100 is turned on, which enables the flow of electrical energy from the source electrode 105 to the substrate 118. The gate electrode contact 114 may comprise a polysilicon material.

The source electrode 105 includes a first metal layer 108, first and second vias 110A, 110B, and a second metal layer 112. The first metal layer 108 includes a first source electrode contact 108A and a second source electrode contact 108B. The second metal layer 112 may be a monolithic source pad operable to convey electrical energy to the first and second source electrode contacts 108A, 108B respectively through the first and second vias 110A, 110B. The second metal layer 112 may extend along a horizontal axis (e.g., the x-axis) between the first via 110A and the second via 110B.

The first and second metal layers 108, 112 and the gate pad 102 may each include a conductive metal, such as aluminum, copper, titanium, gold, and the like, or a combination thereof. In various examples, the first metal layer 108 and the second metal layer 112 may include different or dissimilar metals and/or alloys. In an alternative example, the first and second metal layers 108, 112 may include similar or the same metals and/or alloys.

The gate electrode contact 114 includes first, second, and third fingers 114A, 114B, 114C, and a gate electrode bus 114D. The first finger 114A is located adjacent and laterally spaced (along the x-axis) from the source electrode contact 108A. The second finger 114B is located between and laterally spaced (along the x-axis) from the first and second source electrode contacts 108A, 108B. The first source electrode contact 108A is located between and laterally spaced (along the x-axis) from the first and second fingers 114A, 114B. The third finger 114C is located adjacent and laterally spaced from (along the x-axis) the second source electrode 108B. The second source electrode 108B is located between and laterally spaced from (along the x-axis) the second and third fingers 114B, 114C. The gate electrode bus 114D extends between and is electrically connected to the first, second, and third fingers 114A, 114B, 114C. The first and second source electrode contacts 108A, 108B are spaced from the gate electrode bus 114D along a y-axis, as shown in FIG. 1.

Referring to FIG. 3, the gate via 120 may be positioned generally orthogonal to and extend along the vertical axis between a top surface of the gate electrode contact 114 and a bottom surface of the gate pad 102. In various examples, the gate via 120 may be at least five percent (5%) or at least fifteen percent (15%), but less than eighty percent (80%), less than sixty percent (60%), or less than forty percent (40%), as thick as the first metal layer gate pad 102 or the gate electrode contact 114, in each case considered laterally or along a dimension corresponding to a length of the gate electrode bus 114D (e.g., along the x-axis and/or the y-axis as shown in FIG. 1). The gate via 120 may be taller or have greater height along the vertical axis than the thickness of the first gate pad 102 along the vertical axis.

As shown in FIG. 3, the gate via 120 extends between the gate pad 102 and the gate electrode bus 114D. It would be appreciated by one of ordinary skill in the art that the gate via 120 may contact any and/or all of the first, second, and third fingers 114A, 114B, 114C, and the gate electrode bus 114D without departing from the scope of the present disclosure.

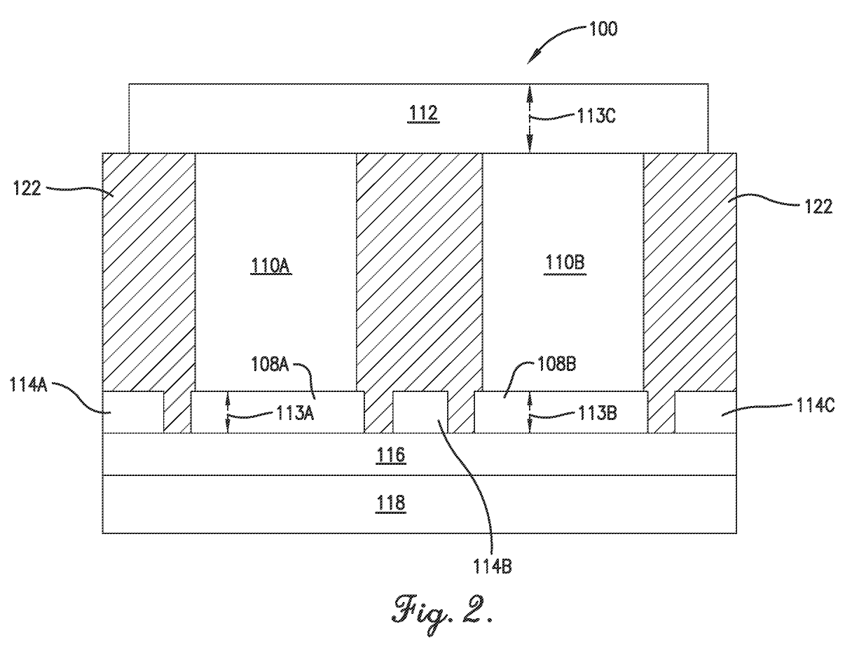

As shown in FIGS. 1 and 2, the first metal layer 108 and the second metal layer 112 are spaced apart along the vertical axis, with the first and second vias 110A, 110B extending between and electrically connecting the first metal layer 108 and the second metal layer 112. The first via 110A extends between the first source electrode contact 108A and the second metal layer 112 along the vertical axis. The second via 110B extends between the second source electrode contact 108B and the second metal layer 112 along the vertical axis.

The first and second vias 110A, 110B are spaced apart along the horizonal axis and positioned generally orthogonal to both the first metal layer 108 and the second metal layer 112. The first via 110A may be positioned generally orthogonal to and extend along the vertical axis between a top surface of the first source electrode contact 108A and a bottom surface of the second metal layer 112. The second via 110B may be positioned generally orthogonal to and extend along the vertical axis between a top surface of the second source electrode contact 108B and the bottom surface of the second metal layer 112.

In various examples, the first and second vias 110A, 110B may be at least five percent (5%) or at least fifteen percent (15%), but may be less than eighty percent (80%), less than sixty percent (60%), or less than forty percent (40%), as thick as the first metal layer 108 or as either of the source electrode contacts 108A, 108B, in each case considered along the x-axis and/or the y-axis as shown in FIG. 1. The vias 110A, 110B may be taller or have greater height than the thickness of the first and second metal layers 108, 112, in each case considered along the vertical axis.

In various examples, the first via 110A, the second via 110B, and the gate via 120 may include an electrically conductive metal, such as copper, aluminum, titanium, gold, and the like, or combinations thereof. The first via 110A, the second via 110B, and the gate via 120 may be formed of different or dissimilar metals and/or alloys. In an alternative example, the first via 110A, the second via 110B, and the gate via 120 may include similar or the same metals and/or alloys. Any of the first via 110A, the second via 110B, and the gate via 120 may include different or dissimilar metals as any of the first metal layer 108, the second metal layer 112, and/or the gate pad 102. In an alternative example, any of the first via 110A, the second via 110B, and the gate via 120 may include similar or the same metals and/or alloys as the any of the first metal layer 108, the second metal layer 112, and/or the gate pad 102.

The second metal layer 112 is electrically connected to a pair of bond wires 106. When the semiconductor device 100 is turned on, the bond wires 106 may apply a voltage to the second metal layer 112 that enables the flow of electrical energy from the second metal layer 112, through the first and second vias 110A, 110B, through the first metal layer 108, and to the substrate 118. The first via 110A may convey electrical energy received from the second metal layer 112 to the first source electrode contact 108A. The second via 110B may convey electrical energy received from the second metal layer 112 to the second source electrode contact 108B.

In various examples, the gate bond wire 104 and the pair of bond wires 106 may each have a thickness of about twenty (20) millimeters (mm) or greater than twenty (20) mm. In some examples, the gate bond wire 104 and the pair of bond wires 106 may have different thicknesses. In other examples, the gate bond wire 104 and the pair of bond wires 106 may have similar thicknesses.

Referring to FIG. 2, the first source electrode contact 108A has a first thickness 113A, the second source electrode contact 108B has a second thickness 113B, and the second metal layer 112 has a third thickness 113C along the vertical axis. In various examples, the first thickness 113A may be a maximum or minimum thickness of the first source electrode contact 108A, the second thickness 113B may be a maximum or minimum thickness of the second source electrode contact 108B, and the third thickness 113C may be a maximum or minimum thickness of the second metal layer 112. The third thickness 113C may be greater than each of the first and second thicknesses 113A, 113B. More particularly, the third thickness 113C may be about twice as great or more than twice as great as each of the first and second thicknesses 113A, 113B. In various examples, the first thickness 113A and the second thickness 113B may each be in a range of about one and one half (1.5) microns to three (3) microns. The third thickness 113C may be in a range of about three (3) to six (6) microns. It would be appreciated by one of ordinary skill in the art that the first, second, and third thicknesses 113A, 113B, 113C may be smaller or greater than the above ranges without departing from the scope of the present disclosure.

Returning to FIG. 1, the gate electrode contact 114 and the first metal layer 108 are located proximate the substrate 118. The passivation layer 116 is interposed between the substrate 118 and each of the gate electrode contact 114 and the first metal layer 108. The passivation layer 116 may include glass based dielectric material, such as borophosphosilicate glass (BPSG), phosphosilicate glass (PSG), fluorosilicate glass (FSG), and the like.

The substrate 118 may include a volume of semiconductor material including various doped material regions corresponding to various transistor components, such as a source, a drain, a drift region, and the like. In various examples, the semiconductor material of the substrate 118 may include silicon carbide (SiC), gallium nitride (GaN), and the like. It would be appreciated by one of ordinary skill in the art that, although not shown, a drain electrode contact may be placed below the substrate 118.

As shown in FIGS. 2 and 3, the semiconductor device 100 additionally includes an insulation layer 122 (indicated by the shaded areas). The insulation layer 122 may extend continuously between the various other numbered components of the semiconductor device 100, effectively filling any space between the components. The insulation layer 122 may extend between the vias 110A, 110B, the gate electrode contact 114, the source electrode contacts 108A, 108B, the passivation layer 116, and the second metal layer 112. The insulation layer 122 may include one or more oxide and/or nitride based dielectric materials, such as silicon dioxide, aluminum oxide, hafnium oxide, polysilicon oxide, phosphorus oxide, silicon nitride, aluminum nitride, titanium nitride, and the like.

In various examples, the second metal layer 112 being a monolithic source pad enables the use of only two (2) bond wires 106 to operate the semiconductor device 100. Accordingly, unwanted parasitics may be reduced my minimizing the number of bond wires, thereby improving performance of the semiconductor device 100. Further, the second metal layer 112 may improve heat dissipation due and convey current uniformly to its monolithic nature, which may further improve the performance of the semiconductor device.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

For example, although described herein with regard or in relation to one or more particular kinds of electronic devices (e.g., metal oxide semiconductor field-effect transistor), the technology may be more broadly applicable to one or more other kinds of electronic devices as well. Further, one with ordinary skill in the art will recognize that the technology described herein may, when applicable, be implemented in enhancement mode or depletion mode. Additionally, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum dioxide, hafnium dioxide, silicon nitride, or other suitable material; and semiconductor material may include silicon carbide, gallium nitride, zinc oxide, or other suitable material.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

According to various examples of the present disclosure, a semiconductor device may include a source electrode. The source electrode may include spaced apart first and second metal layers and a via extending between and electrically connecting the first metal layer and the second metal layer.

In combination with any of the previous examples, a first metal layer may include a first source electrode contact and a second source electrode contact. A via may be a first via extending between the first source electrode contact and a second metal layer.

In combination with any of the previous examples, a semiconductor device may include a substrate, a gate electrode contact disposed proximate the substrate, a gate pad spaced apart from the gate electrode contact, and a gate via extending between the gate pad and the gate electrode contact.

In combination with any of the previous examples, a gate electrode contact may include a first finger adjacent the first source electrode contact, a second finger located between first and second source electrode contacts, a third finger adjacent the second source electrode contact, and a gate electrode bus extending between and electrically connecting the first, second, and third finger sections.

In combination with any of the previous examples, a gate via may be electrically connected to a gate electrode bus.

In combination with any of the previous examples, a gate bond wire may be electrically connected to a gate pad.

In combination with any of the previous examples, a second metal layer may include a source pad. A semiconductor device may include a second via extending between and electrically connecting a second source electrode contact and the source pad.

In combination with any of the previous examples, a source pad may be monolithic extending between a first via and a second via.

In combination with any of the previous examples, a semiconductor device may include a pair of bond wires electrically connected to a source pad.

In combination with any of the previous examples, a first metal layer may have a first maximum thickness, and a second metal layer have a second maximum thickness. The second maximum thickness may be greater than the first maximum thickness.

In combination with any of the previous examples, a second maximum thickness may be at least twice as great as a first maximum thickness.

In combination with any of the previous examples, a semiconductor device may include a substrate and a passivation layer interposed between a first metal layer and the substrate. The first metal layer may be disposed on the passivation layer.

In combination with any of the previous examples, a passivation layer may include borophosphosilicate glass (BPSG).

In combination with any of the previous examples, a semiconductor device may include a substrate including silicon carbide (SiC).

According to various examples of the present disclosure, a semiconductor device may include first and second source electrode contacts and a monolithic source pad spaced apart from and electrically connected to the first and second source electrodes.

In combination with any of the previous examples, a semiconductor device may include a first via extending between a first source electrode contact and a monolithic source pad and a second via extending between a second source electrode contact and the monolithic source pad.

In combination with any of the previous examples, a semiconductor device may include a substrate, a gate electrode contact disposed proximate the substrate, a gate pad spaced apart from the gate electrode contact, and a gate via extending between the gate pad and the gate electrode contact. At least a portion of the gate electrode contact may extend between the first and second source electrode contacts.

In combination with any of the previous examples, a first source electrode contact may have a first maximum thickness, a second source electrode contact may have a second maximum thickness. The first and second maximum thickness may be equal. A monolithic source pad may have a third maximum thickness. The third maximum thickness may be greater than both the first maximum thickness and the second maximum thickness.

In combination with any of the previous examples, a third maximum thickness may be at least twice as great as both a first maximum thickness and a second maximum thickness.

In combination with any of the previous examples, a semiconductor device may include a pair of bond wires electrically connected to a monolithic source pad.

What is claimed is:

1. A semiconductor device, comprising:
a source electrode including –
spaced first and second metal layers; and
a via extending between and electrically connecting the first metal layer and the second metal layer.

2. The semiconductor device of claim 1, the first metal layer comprising a first source electrode contact and a second source electrode contact, wherein the via is a first via extending between the first source electrode contact and the second metal layer.

3. The semiconductor device of claim 2, comprising:
a substrate;
a gate electrode contact disposed proximate the substrate;
a gate pad spaced apart from the gate electrode contact; and
a gate via extending between the gate pad and the gate electrode contact.

4. The semiconductor device of claim 3, the gate electrode contact including:
a first finger adjacent the first source electrode contact;
a second finger located between the first and second source electrode contacts;
a third finger adjacent the second source electrode contact; and
a gate electrode bus extending between and electrically connecting the first, second, and third finger sections.

5. The semiconductor device of claim 4,
the gate via being electrically connected to the gate electrode bus.

6. The semiconductor device of claim 3, comprising:
a gate bond wire electrically connected to the gate pad.

7. The semiconductor device of claim 2, the second metal layer comprising a source pad, comprising:
a second via extending between and electrically connecting the second source electrode contact and the source pad.

8. The semiconductor device of claim 7, the source pad being monolithic and extending between the first via and the second via.

9. The semiconductor device of claim 8, comprising:
a pair of bond wires electrically connected to the source pad.

10. The semiconductor device of claim 1,
the first metal layer having a first maximum thickness,
the second metal layer having a second maximum thickness,
the second maximum thickness being greater than the first maximum thickness.

11. The semiconductor device of claim 10,
the second maximum thickness being at least twice as great as the first maximum thickness.

12. The semiconductor device of claim 1, comprising:
a substrate; and
a passivation layer interposed between the first metal layer and the substrate, the first metal layer being disposed on the passivation layer.

13. The semiconductor device of claim 12, the passivation layer including borophosphosilicate glass (BPSG).

14. The semiconductor device of claim 1, comprising a substrate including silicon carbide (SiC).

15. A semiconductor device, comprising:
first and second source electrode contacts; and
a monolithic source pad spaced apart from and electrically connected to the first and second source electrodes.

16. The semiconductor device of claim 15, comprising:
a first via extending between the first source electrode contact and the monolithic source pad; and
a second via extending between the second source electrode contact and the monolithic source pad.

17. The semiconductor device of claim 15, comprising:
a substrate;
a gate electrode contact disposed proximate the substrate, at least a portion of the gate electrode contact extending between the first and second source electrode contacts;
a gate pad spaced apart from the gate electrode contact; and
a gate via extending between the gate pad and the gate electrode contact.

18. The semiconductor device of claim 15,
the first source electrode contact having a first maximum thickness,
the second source electrode contact having a second maximum thickness, the first and second maximum thickness being equal,
the monolithic source pad having a third maximum thickness, the third maximum thickness being greater than both the first maximum thickness and the second maximum thickness.

19. The semiconductor device of claim 18,
the third maximum thickness being at least twice as great as both the first maximum thickness and the second maximum thickness.

20. The semiconductor device of claim 15, comprising:
a pair of bond wires electrically connected to the monolithic source pad.
